(19) United States
(12) Patent Application Publication
(10) Pub. No.: US 2012/0086020 A1
(43) Pub. Date: Apr. 12, 2012

(54) Integrated photodetecting device

(75) Inventors: Yan-Kuin Su, Tainan City (TW); Shyh-Jer Huang, Tainan City (TW); Chen-Fu Lin, Kaohsiung City (TW)

(73) Assignee: National Cheng Kung University, Tainan City (TW)

(21) Appl. No.: 13/064,648

(22) Filed: Apr. 6, 2011

(30) Foreign Application Priority Data
Oct. 7, 2010 (TW) 099134137

(51) Int. Cl. H01L 31/173

(52) U.S. Cl. 257/84; 257/E31.109

(57) ABSTRACT

This invention relates to an integrated photodetecting device. The integrated photodetecting device includes a substrate, a light source layer and a photodetector layer. The photodetector layer and light source layer are epitaxied in a stacked structure. The whole device in this invention is fabricated by epitaxy method during a single process. Therefore, the production cost can be reduced by the omission of alignment process. Besides, the integrated photodetecting device of the invention integrates the light source and photodetector into one chip, hence has the ability of minimization, resulting in the reduction of consumption of samples and test time. The distance between the photodetector layer and targets to be tested can also be largely reduced, making the accuracy and sensitivity largely improved, and the kinds of detectable targets largely increased. Furthermore, the integrated photodetecting device of the invention is a portable device so as to increase the possibility of preventive medicine.

### CROSS REFERENCE TO RELATED APPLICATION

This application claims the benefits of the Taiwan Patent Application Serial Number 099134137, filed on Oct. 7, 2010, the subject matter of which is incorporated herein by reference.

### BACKGROUND OF THE INVENTION

1. Field of the Invention

The present invention relates to a photodetecting device and, more particularly, to an integrated photodetecting device.

2. Description of Related Art

In order to achieve detection function, commonly used conventional optical biosensors are designed as machines having the assembly of a light source and a photodetector. However, the large, heavy and high-cost conventional optical biosensors are not portable and not suitable for personal use. In addition, for these conventional optical biosensors, a large amount of tested target and long detecting time are required, and their low accuracy and sensitivity limit the detectable range of tested targets.

FIG. 1 shows a cross-sectional view of a conventional photodetecting device. As shown in FIG. 1, the conventional photodetecting device 10 for detecting sample molecules 16 includes: a substrate 11, a photodetector layer 12, a filter layer 13, a bonding pad and reflector 14, and a light source 15. Accordingly, when light 17 is emitted by the light source 15 and transmitted to the sample molecules 16, the sample molecules 16 will absorb the light 17 from the light source 15 and emit another light 18 with different wavelength from the light 17, and then the light 18 will pass through the filter layer 13 and be detected by the photodetector layer 12.

The method for preparing the conventional photodetecting device 10 includes the following steps: forming a photodetector layer 12 on the substrate 11; sputtering a filter layer 13 on the photodetector layer 12 to selectively block the light emitted by the light source 15; removing the substrate bonding to the light source 15 by a laser liftoff process; and bonding the light source 15 onto the filter layer 13 via the bonding pad and reflector 14. However, the above-mentioned complex process for manufacturing the conventional photoelectric sensor 10 causes the increase of manufacturing cost, and the accuracy and sensitivity are reduced by the bonding pad and reflector 14 and the filter layer 13.

Therefore, it is desirable to provide a novel integrated photodetecting device to obviate the aforementioned problems.

### SUMMARY OF THE INVENTION

The present invention provides a first aspect of a novel integrated photodetecting device, including a substrate, a light source layer and a photodetector layer. Herein, the light source layer is epitaxied above the substrate, and the photodetector layer is epitaxied above the light source layer.

The novel integrated photodetecting device according to the first aspect may further include a driving controller, which is connected to the light source layer and the photodetector layer and capable of providing a lighting driving signal and a photodetecting driving signal.

The novel integrated photodetecting device according to the first aspect may further include a filter layer epitaxied between the light source layer and the photodetector layer. Accordingly, the filter layer can be used for blocking light emitted by the light source layer.

The present invention also provides a method for fabricating the integrated photodetecting device according to the first aspect, including the following steps: (a) providing a substrate; (b) epitaxing a light source layer above the substrate; and (c) epitaxing a photodetector layer above the light source layer.

The method for fabricating the integrated photodetecting device according to the first aspect may further include a step (d) after the step (c): connecting a driving controller to the light source layer and the photodetector layer for providing a lighting driving signal and a photodetecting driving signal.

The method for fabricating the integrated photodetecting device according to the first aspect may further include a step (b1) between the step (b) and the step (c): epitaxing a filter layer above the light source layer, and the photodetector layer is epitaxied above the filter layer. Accordingly, the filter layer can be used for blocking light emitted by the light source layer.

The present invention further provides a second aspect of a novel integrated photodetecting device, including a substrate, a photodetector layer and a light source layer. Herein, the photodetector layer light source layer is epitaxied above the substrate, and the light source layer is epitaxied above the photodetector layer.

The novel integrated photodetecting device according to the second aspect may further include a driving controller, which is connected to the light source layer and the photodetector layer and capable of providing a lighting driving signal and a photodetecting driving signal.

The novel integrated photodetecting device according to the second aspect may further include a filter layer epitaxied between the light source layer and the photodetector layer. Accordingly, the filter layer can be used for blocking light emitted by the light source layer.

The present invention also provides a method for fabricating the integrated photodetecting device according to the second aspect, including: (a) providing a substrate; (b) epitaxing a photodetector layer above the substrate; and (c) epitaxing a light source layer above the photodetector layer.

The method for fabricating the integrated photodetecting device according to the second aspect may further include a step (d) after the step (c): connecting a driving controller to the light source layer and the photodetector layer for providing a lighting driving signal and a photodetecting driving signal.

The method for fabricating the integrated photodetecting device according to the second aspect may further include a step (b1) between the step (b) and the step (c): epitaxing a filter layer above the photodetector layer, and the light source layer is epitaxied above the filter layer. Accordingly, the filter layer can be used for blocking light emitted by the light source layer.

In the present invention, the substrate may be a sapphire substrate, a silicon carbide substrate, a magnesium oxide substrate, a gallium oxide substrate, a lithium gallium oxide substrate, a lithium aluminum oxide substrate, a spinel substrate, a silicon substrate, a germanium substrate, a gallium arsenide substrate, a gallium phosphide substrate, a glass substrate or a zirconium diboride substrate. Preferably, the substrate used in the integrated photodetecting device according to the first aspect is a transparent substrate.

In the present invention, the light source layer and the photodetector layer may be made of III-V binary compounds, ternary compounds or quaternary compounds. Preferably, the light source layer is a solid-state light source layer made of nitride-based materials, and the photodetector layer is a photodetector layer made of nitride-based materials. Herein, the nitride-based materials may be nitride-based compounds contain nitrogen and one or more elements of aluminum, gallium and indium. Examples of the nitride-based materials include, but are not limited to, GaN, MN, InN, AlGaN, AlInN, GaInN and AlInGaN.

In the present invention, preferably, the lighting driving signal and the photodetecting driving signal are provided during different periods and their driving periods do not overlap.

In the novel integrated photodetecting devices and the methods for fabricating the same according to the present invention, the light source layer and the photodetector layer are epitaxied in a stacked structure, unlike the conventional measurement equipments in which the light source layer and the photodetector layer are combined in an assembly manner. According to the present invention, since the integrated photodetecting device can be obtained by a single epitaxy process, the epitaxy cost and assembly cost can be significantly reduced, and the alignment process can be omitted.

Moreover, the present invention can integrate the light source and the photodetector into one single chip and thus can significantly reduce the scale, shorten the distance between the photodetector and targets so as to improve the accuracy and sensitivity, detect more kinds of targets, and reduce the consumption of samples and test time. In particular, the integrated photodetecting device according to the present invention is a portable device and hence is advantageous in the development of preventive medicine.

Other objects, advantages, and novel features of the invention will become more apparent from the following detailed description when taken in conjunction with the accompanying drawings.

### BRIEF DESCRIPTION OF THE DRAWINGS

FIG. 1 shows a cross-sectional view of a conventional photodetecting device;

FIG. 2 shows a cross-sectional view of an integrated photodetecting device according to the first embodiment of the present invention;

FIG. 3 shows a cross-sectional view of an integrated photodetecting device according to the second embodiment of the present invention;

FIG. 4 shows a cross-sectional view of an integrated photodetecting device according to the third embodiment of the present invention;

FIG. 5 shows a cross-sectional view of an integrated photodetecting device according to the fourth embodiment of the present invention;

FIG. 6 shows an energy gap vs. lattice constant diagram of zinc blende structure;

FIG. 7 shows an energy gap vs. lattice constant diagram of zinc wurtzite structure;

FIG. 8 shows a schematic view to illustrate that fluorescent particles are detected by an integrated photodetecting device according to the third embodiment of the present invention;

FIG. 9 shows a schematic diagram to illustrate that the light source layer and the photodetector layer are driven during different periods;

FIG. 10 shows a cross-sectional view of an integrated photodetecting device according to the fifth embodiment of the present invention; and

FIG. 11 shows a cross-sectional view of an integrated photodetecting device according to the sixth embodiment of the present invention.

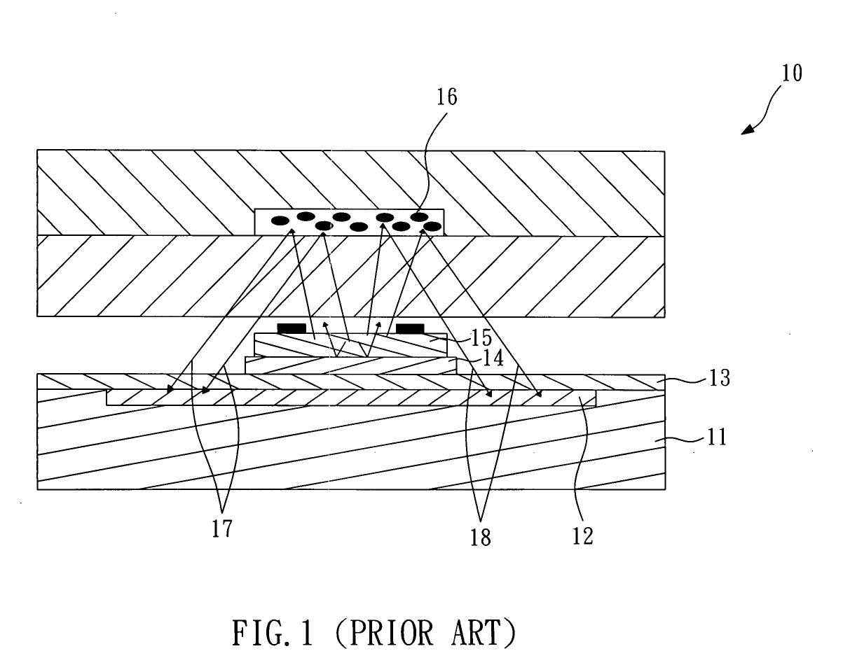

### DETAILED DESCRIPTION OF THE PREFERRED EMBODIMENT

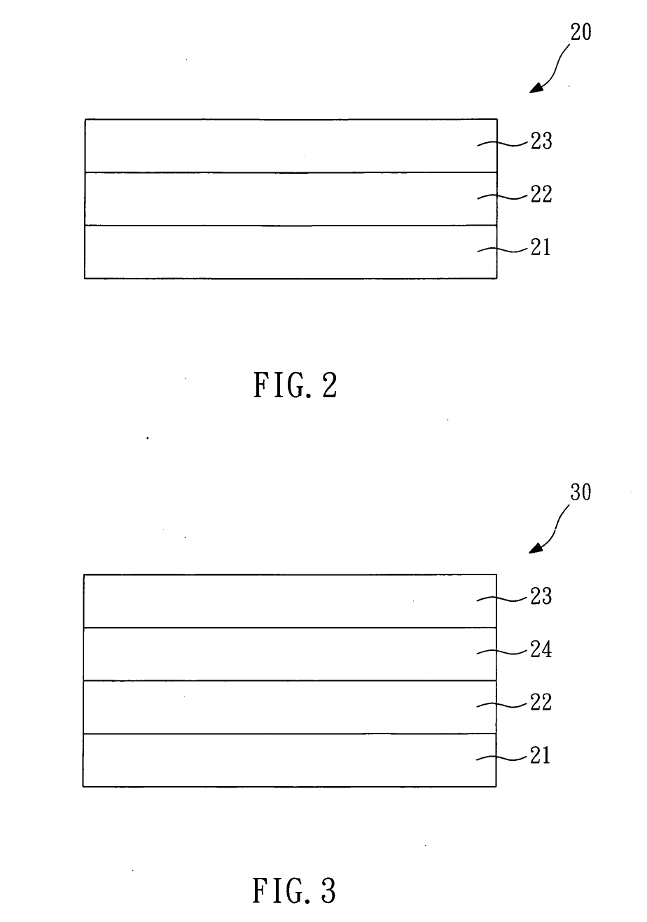

FIG. 2 shows a cross-sectional view of an integrated photodetecting device according to the first embodiment of the present invention. As shown in FIG. 2, the integrated photodetecting device 20 according to the first embodiment of the present invention includes: a substrate 21, a light source layer 22 and a photodetector layer 23. Herein, the light source layer 22 is epitaxied on the substrate 21, and the photodetector layer 23 is epitaxied on the light source layer 22.

In the present embodiment, the substrate 21 is a sapphire substrate, a silicon carbide substrate, a magnesium oxide substrate, a gallium oxide substrate, a lithium gallium oxide substrate, a lithium aluminum oxide substrate, a spinel substrate, a silicon substrate, a germanium substrate, a gallium arsenide substrate, a gallium phosphide substrate, a glass substrate or a zirconium diboride substrate.

In the present embodiment, the light source layer 22 and the photodetector layer 23 are made of III-V binary compounds, ternary compounds or quaternary compounds consisting of at least one group III element (such as Al, Ga, In) and at least one group V element (such as N, P, As, Sb). Additionally, the light source layer 22 and the photodetector layer 23 are different in energy gap.

In the present embodiment, the light source layer 22 is a solid-state light source layer made of nitride-based materials, and the photodetector layer 23 is a photodetector layer made of nitride-based materials. Herein, the nitride-based materials contain nitrogen and one or more elements of aluminum, gallium and indium.

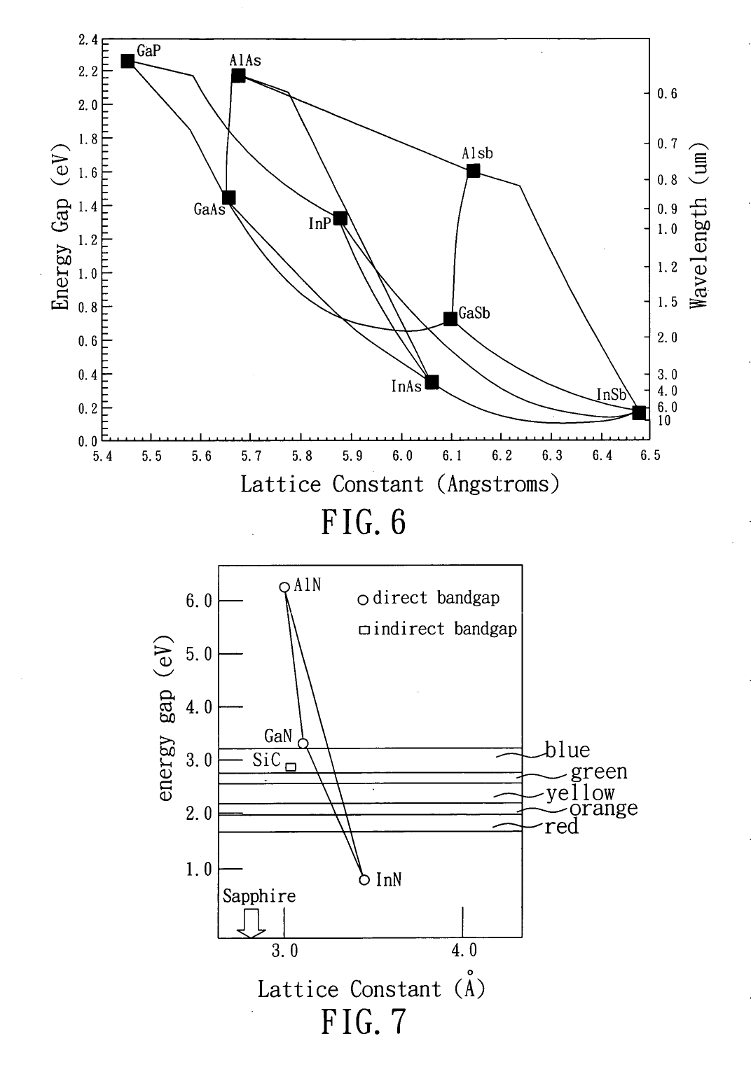

Since the light source layer 22 and the photodetector layer 23 are epitaxied in a stacked structure, the lattice of the light source layer 22 matches that of the photodetector layer 23. The lattice structure of III-V materials includes zinc blende structure and wurtzite structure, and their energy gap vs. lattice constant diagrams are shown in FIGS. 6 and 7, respectively. The nitride-based materials include, for example, GaN, InN, AlGaN, AlInN, GaInN and AlInGaN, and their energy gaps and lattice constants can be determined from FIG. 7, in which the light colors corresponding to various energy gaps are indicated.

As shown in FIG. 7, the energy gap and lattice constant of GaN, InN and AlN can be determined from the GaN point, the InN point and the AlN point, respectively; the energy gap and lattice constant of GaInN, AlGaN and AlInN vary along the line between the GaN point and the InN point, the line between the AlN point and the GaN point, and the line between the AlN point and the InN point based on the mixture ratio of GaN:InN, AlN:GaN, and AlN:InN, respectively; and the energy gap and lattice constant of AlInGaN vary in the triangle region defined by the GaN point, the InN point and the AlN point based on the mixture ratio of GaN:InN:MN.

Moreover, preferably, a layer containing more indium is epitaxied after the formation of a layer containing less indium due to that the layer containing more indium cannot be placed at high temperature for long time. Taking a device in which a blue light source layer and a green photodetector layer are used for example, since indium contained in the blue light source layer is less than that contained in the green photodetector layer, the green photodetector layer preferably is epitaxied after the formation of the blue light source layer so as to maintain good lattice quality and high performance. Thereby, in the present embodiment, the light source layer 22 is first epitaxied on the substrate 21, and then the photodetector layer 23 is epitaxied on the light source layer 22.

In order to place fluorescent particles close to the light source layer 22, the integrated photodetecting device 20 according to the first embodiment of the present invention can be used in an inverse state to locate the substrate 21 at the upper side, such that the fluorescent particles can be placed above the substrate 21. Herein, a transparent substrate (such as a transparent sapphire substrate) is used as the substrate 21 so as to allow light of about 400 nm from the light source layer 22 to pass through the substrate 21 and to excite the fluorescent particles, resulting in emission of green light of about 500 nm from the fluorescent particles. The green light of about 500 nm can be absorbed by the photodetector layer 23 and converted into electronic signal, such that the concentration of the fluorescent particles can be determined based on the electronic signal. Accordingly, the photodetecting device of the present invention can excite fluorescence of targets and simultaneously detect its intensity.

FIG. 3 shows a cross-sectional view of an integrated photodetecting device according to the second embodiment of the present invention. In comparison with the integrated photodetecting device 20 according to the first embodiment of the present invention, the integrated photodetecting device 30 according to the second embodiment of the present invention further includes a filter layer 24 epitaxied between the light source layer 22 and the photodetector layer 23. Herein, the filter layer 24 is used to block light emitted from the light source layer 22. For example, the filter layer 24 can block the light of 400 nm from the light source layer 22 and thus prevents the light emitted by the photodetector layer 23 from interfering with the photodetector layer 23.

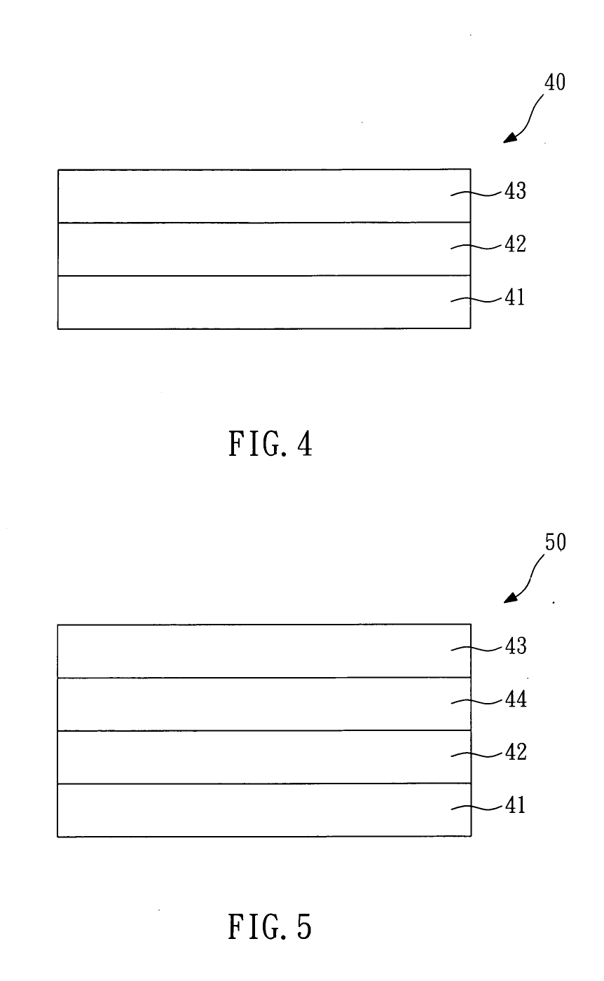

FIG. 4 shows a cross-sectional view of an integrated photodetecting device according to the third embodiment of the present invention. As shown in FIG. 4, the integrated photodetecting device 40 according to the third embodiment of the present invention includes: a substrate 41, a photodetector layer 42 and a light source layer 43. Herein, the photodetector layer 42 is epitaxied on the substrate 41, and the light source layer 43 is epitaxied on the photodetector layer 42.

In the integrated photodetecting device 40 according to the third embodiment of the present invention, the materials of the substrate 41, the photodetector layer 42 and the light source layer 43 are the same as those of the substrate 21, the light source layer 22 and the photodetector layer 23 in the integrated photodetecting device 20 according to the first embodiment of the present invention.

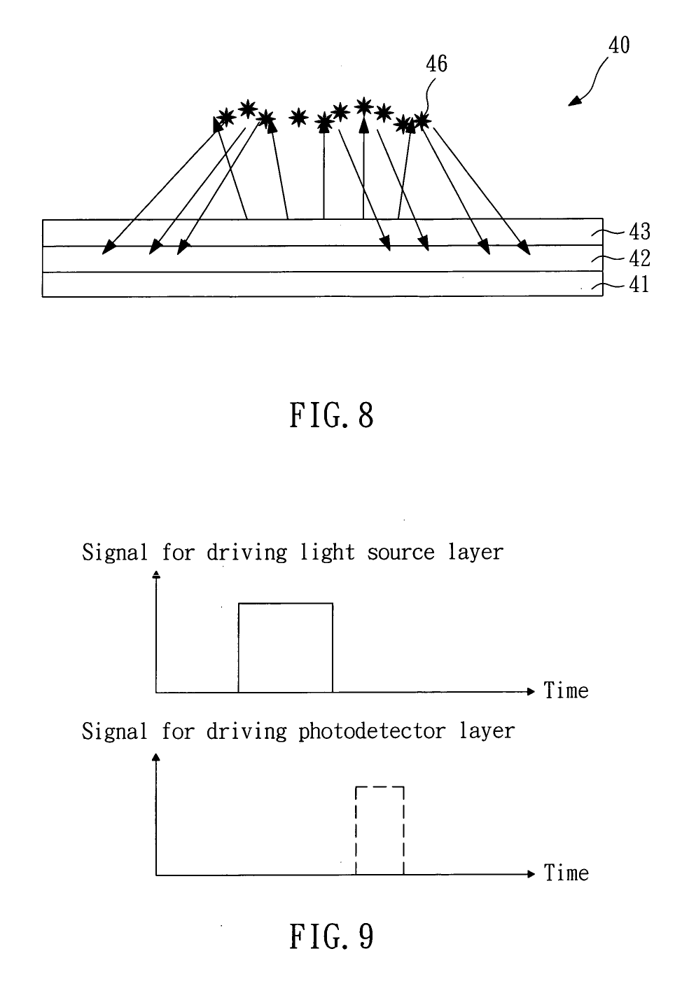

In the present embodiment, as shown in FIG. 8, fluorescent particles 46 can be placed above and close to the light source layer 43 at the upper side when being tested. Herein, the light emitted by the light source layer 43 (about 400 nm) may be absorbed by the photodetector layer 42 in addition to the light from the fluorescent particles 46 (about 500 nm), and thereby the photodetector layer 42 is preferably disposed between the light source layer 43 and the substrate 41 to reduce the interference from light emitted by the light source layer 43 and the possibility of light from the light source layer 43 being absorbed by the photodetector layer 42 so as to maintain the light power from the light source layer 43.

FIG. 5 shows a cross-sectional view of an integrated photodetecting device according to the fourth embodiment of the present invention. In comparison with the integrated photodetecting device 40 according to the third embodiment of the present invention, the integrated photodetecting device 50 according to the fourth embodiment of the present invention further includes a filter layer 44 epitaxied between the light source layer 43 and the photodetector layer 42. Herein, the filter layer 44 is used to block light emitted from the light source layer 43. For example, the filter layer 44 can block the light of 400 nm from the light source layer 43 and thus prevents the light emitted by the photodetector layer 42 from interfering with the photodetector layer 42.

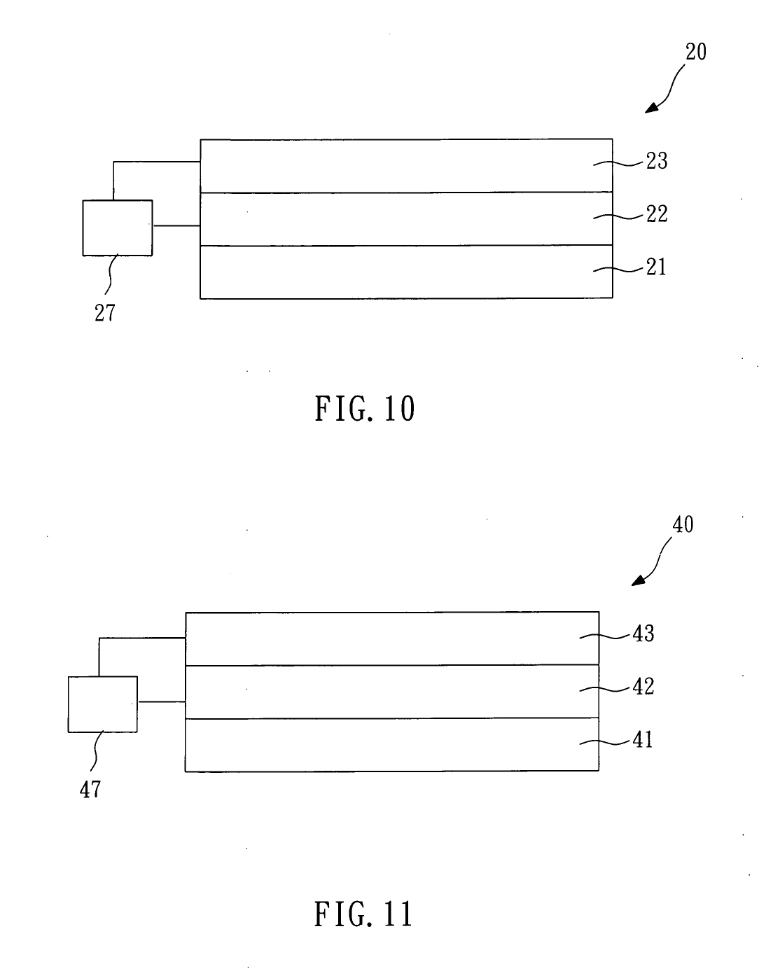

Even if no filter layer is used, the interference between the light source layer and the photodetector layer also can be reduced by controlling the driving periods of the light source layer and the photodetector layer. FIG. 9 shows a schematic diagram to illustrate that the light source layer and the photodetector layer are driven during different periods. Accordingly, as a fifth embodiment and a sixth embodiment of the present invention, the integrated photodetecting device 20 of the first embodiment and the integrated photodetecting device 40 of the third embodiment can further include a driving controller 27, 47, which is connected to the light source layer 23, 42 and the photodetector layer 22, 43 to provide a lighting driving signal and a photodetecting driving signal, as shown in FIGS. 10 and 11. Herein, the lighting driving signal and the photodetecting driving signal are provided during different periods and their driving periods do not overlap. Accordingly, the interference between the light source layer and the photodetector layer can be reduced by controlling the driving periods of the light source layer and the photodetector layer without disposing a filter layer and limiting the locations of the light source layer and the photodetector layer.

In the integrated photodetecting device according to the present invention, the light source layer and the photodetector layer are epitaxied in a stacked structure, unlike the conventional measurement equipments in which the light source layer and the photodetector layer are combined in an assembly manner. According to the present invention, since the integrated photodetecting device can be obtained by a single epitaxy process, the epitaxy cost and assembly cost can be significantly reduced, and the alignment process can be omitted.

In addition, the present invention can integrate the light source and the photodetector into one single chip and thus can significantly reduce the scale, shorten the distance between the photodetector and targets so as to improve the accuracy and sensitivity, detect more kinds of targets, and reduce the consumption of samples and test time. In particular, the integrated photodetecting device according to the present invention is a portable device and hence is advantageous in the development of preventive medicine.

Although the present invention has been explained in relation to its preferred embodiment, it is to be understood that many other possible modifications and variations can be made without departing from the spirit and scope of the invention as hereinafter claimed.

What is claimed is:

1. An integrated photodetecting device, comprising:
a substrate;
a light source layer, epitaxied above the substrate; and
a photodetector layer, epitaxied above the light source layer.

2. The integrated photodetecting device as claimed in claim 1, wherein the substrate is a sapphire substrate, a silicon carbide substrate, a magnesium oxide substrate, a gallium oxide substrate, a lithium gallium oxide substrate, a lithium aluminum oxide substrate, a spinel substrate, a silicon substrate, a germanium substrate, a gallium arsenide substrate, a gallium phosphide substrate, a glass substrate or a zirconium diboride substrate.

3. The integrated photodetecting device as claimed in claim 1, wherein the light source layer and the photodetector layer are made of III-V binary compounds, ternary compounds or quaternary compounds.

4. The integrated photodetecting device as claimed in claim 1, wherein the light source layer is a solid-state light source layer made of nitride-based materials.

5. The integrated photodetecting device as claimed in claim 4, wherein the nitride-based materials are nitride-based compounds contain nitrogen and one or more elements of aluminum, gallium and indium.

6. The integrated photodetecting device as claimed in claim 1, wherein the photodetector layer is a photodetector layer made of nitride-based materials.

7. The integrated photodetecting device as claimed in claim 6, wherein the nitride-based materials are nitride-based compounds contain nitrogen and one or more elements of aluminum, gallium and indium.

8. The integrated photodetecting device as claimed in claim 1, further comprising: a filter layer, epitaxied between the light source layer and the photodetector layer.

9. The integrated photodetecting device as claimed in claim 8, wherein the filter layer is used for blocking light emitted by the light source layer.

10. The integrated photodetecting device as claimed in claim 1, wherein the substrate is a transparent substrate.

11. The integrated photodetecting device as claimed in claim 1, further comprising: a driving controller connected to the light source layer and the photodetector layer and capable of providing a lighting driving signal and a photodetecting driving signal, wherein the lighting driving signal and the photodetecting driving signal are provided during different periods and their driving periods do not overlap.

12. An integrated photodetecting device, comprising:
a substrate;
a photodetector layer, epitaxied above the substrate; and
a light source layer, epitaxied above the photodetector layer.

13. The integrated photodetecting device as claimed in claim 12, wherein the substrate is a sapphire substrate, a silicon carbide substrate, a magnesium oxide substrate, a gallium oxide substrate, a lithium gallium oxide substrate, a lithium aluminum oxide substrate, a spinel substrate, a silicon substrate, a germanium substrate, a gallium arsenide substrate, a gallium phosphide substrate, a glass substrate or a zirconium diboride substrate.

14. The integrated photodetecting device as claimed in claim 12, wherein the light source layer and the photodetector layer are made of III-V binary compounds, ternary compounds or quaternary compounds.

15. The integrated photodetecting device as claimed in claim 12, wherein the light source layer is a solid-state light source layer made of nitride-based materials.

16. The integrated photodetecting device as claimed in claim 15, wherein the nitride-based materials are nitride-based compounds contain nitrogen and one or more elements of aluminum, gallium and indium.

17. The integrated photodetecting device as claimed in claim 12, wherein the photodetector layer is a photodetector layer made of nitride-based materials.

18. The integrated photodetecting device as claimed in claim 17, wherein the nitride-based materials are nitride-based compounds contain nitrogen and one or more elements of aluminum, gallium and indium.

19. The integrated photodetecting device as claimed in claim 12, further comprising: a filter layer, epitaxied between the light source layer and the photodetector layer.

20. The integrated photodetecting device as claimed in claim 19, wherein the filter layer is used for blocking light emitted by the light source layer.

21. The integrated photodetecting device as claimed in claim 12, further comprising: a driving controller connected to the light source layer and the photodetector layer and capable of providing a lighting driving signal and a photodetecting driving signal, wherein the lighting driving signal and the photodetecting driving signal are provided during different periods and their driving periods do not overlap.
